(19) United States
(12) Patent Application Publication
(10) Pub. No.: US 2023/0047936 A1
(43) Pub. Date: Feb. 16, 2023

(54) FILTER CIRCUIT

(71) Applicant: Mitsubishi Electric Corporation, Tokyo (JP)

(72) Inventor: Fujiyuki NAKAMOTO, Tokyo (JP)

(73) Assignee: Mitsubishi Electric Corporation, Tokyo (JP)

(21) Appl. No.: 17/976,112

(22) Filed: Oct. 28, 2022

Related U.S. Application Data
(63) Continuation of application No. PCT/JP2021/021653, filed on Jun. 8, 2021.

(30) Foreign Application Priority Data
Jun. 10, 2020 (JP) PCT/JP2020/022880

(51) Int. Cl. H05K 1/02

(52) U.S. Cl. CPC H05K 1/0233; H05K 1/0298; H05K 1/0231; H05K 2201/09227

(57) ABSTRACT

A filter circuit includes: a wiring pattern provided in an upper wiring layer of a printed circuit board, a wiring pattern provided in a lower wiring layer of the printed circuit board, a wiring pattern extending from one end of the wiring pattern, a wiring pattern provided so as to partially face the wiring pattern in the upper wiring layer, a bypass capacitor provided in the upper wiring layer and connected to the wiring pattern and a ground conductor surface, a via connecting one end of the wiring pattern and the wiring pattern, and a via connecting the wiring pattern and the wiring pattern. A structure including the wiring pattern, the via, and the wiring pattern faces a structure including the via and the wiring pattern.

### CROSS REFERENCE TO RELATED APPLICATIONS

This application is a Continuation of PCT International Application No. PCT/JP2021/021653 filed on Jun. 8, 2021, which claims priority under 35 U.S.C. § 119(a) to Patent Application No. PCT/JP2020/022880 filed in Japan on Jun. 10, 2020, all of which are hereby expressly incorporated by reference into the present application.

### TECHNICAL FIELD

The present disclosure relates to a filter circuit.

### BACKGROUND ART

Electronic devices are commonly equipped with a filter circuit that removes electromagnetic noise in a high frequency band leaking from a circuit element such as a large scale integrated circuit (LSI) or an integrated circuit (IC). For example, a conventional filter circuit described in Patent Literature 1 has a printed circuit board mounted with a power supply wiring pattern, a bypass capacitor, a ground conductor surface, a via, and adjacent wiring lines and a wiring line that are a part of the power supply wiring pattern. The adjacent wiring lines are connected in series using the wiring line, and form a mutual inductance by magnetic coupling. The parasitic inductance of a bypass circuit including the bypass capacitor is canceled by a negative inductance equivalently appearing corresponding to the mutual inductance.

### CITATION LIST

### Patent Literature

Patent Literature 1: JP 2017-34115 A

### SUMMARY OF INVENTION

### Technical Problem

The filter circuit described in Patent Literature 1 has a problem of an increase in structure and incapable of sufficiently suppressing the deterioration of bypass performance due to the parasitic inductance of wiring used for mounting the bypass capacitor.

The present disclosure addresses the above problem, and an object of the present disclosure is to obtain a filter circuit that can be downsized in structure and can suppress the deterioration of bypass performance due to the parasitic inductance of wiring used for mounting a bypass capacitor.

### Solution to Problem

The filter circuit according to the present disclosure includes: a first wire; a bypass capacitor; a second wire provided on a plane different from the first wire and placed at a position overlapping the first wire in planar view; a third wire extending from one end of the second wire; a fourth wire provided on a same plane as the first wire and partially facing the first wire; a first connection conductor that connects one end of the first wire and an opposite end of the second wire from the third wire; a second connection conductor that connects a first electrode terminal of the bypass capacitor to the third wire; a third connection conductor that connects a second electrode terminal of the bypass capacitor to a ground conductor surface; and a fourth connection conductor that electrically connects the third wire and the fourth wire, wherein a first structure including the first wire, the first connection conductor, and the second wire faces a second structure including the fourth wire and the fourth connection conductor.

### Advantageous Effects of Invention

According to the present disclosure, the filter circuit includes: a first wire; a bypass capacitor; a second wire provided on a plane different from the first wire and placed at a position overlapping the first wire in planar view; a third wire extending from one end of the second wire; a fourth wire provided on a same plane as the first wire and partially facing the first wire; a first connection conductor that connects one end of the first wire and an opposite end of the second wire from the third wire; a second connection conductor that connects a first electrode terminal of the bypass capacitor to the third wire; a third connection conductor that connects a second electrode terminal of the bypass capacitor to a ground conductor surface; and a fourth connection conductor that connects the third wire and the fourth wire. The first structure including the first wire, the first connection conductor, and the second wire faces the second structure including the fourth wire and the fourth connection conductor. The lengths of portions of the first wire and the fourth wire facing each other can be decreased, and thus, the structure can be downsized. In addition, the first structure and the second structure form a mutual inductance by magnetic coupling, and the parasitic inductance of a bypass circuit including the bypass capacitor is canceled by a negative inductance equivalently appearing corresponding to the mutual inductance. Thus, the filter circuit according to the present disclosure can be downsized in structure and can suppress the deterioration of bypass performance due to the parasitic inductance of wiring used for mounting the bypass capacitor.

### BRIEF DESCRIPTION OF DRAWINGS

FIG. 1A is a cross-sectional view illustrating a printed circuit board provided with a filter circuit according to a first embodiment, FIG. 1B is a plan view illustrating the filter circuit according to a first embodiment provided in a first surface of the printed circuit board illustrated in FIG. 1A, and FIG. 1C is a plan view illustrating the filter circuit according to the first embodiment provided in a second surface of the printed circuit board illustrated in FIG. 1A.

FIG. 2 is a transparent perspective view illustrating a configuration of the filter circuit according to the first embodiment.

FIG. 3A is a circuit diagram schematically illustrating a mutual induction circuit including a parasitic inductor of a structure including a first wire, a first connection conductor, and a second wire, and a parasitic inductor of a structure including a fourth connection conductor and a fourth wire, and FIG. 3B is a circuit diagram illustrating a T-type equivalent circuit of the mutual induction circuit illustrated in FIG. 3A.

FIG. 4 is a circuit diagram schematically illustrating a main part of the equivalent circuit of the filter circuit according to the first embodiment.

FIG. 5 is a graph illustrating an electromagnetic-field calculation result of an S parameter (S₂₁) representing filter performance.

FIG. 6 is a diagram illustrating a wiring loop in the filter circuit according to the first embodiment.

FIG. 7 is a diagram illustrating a relationship between facing wiring loops and a magnetic field generated in the wiring loops in the filter circuit according to the first embodiment.

FIG. 8 is a transparent perspective view illustrating a configuration of a filter circuit according to a second embodiment.

FIG. 9 is a transparent perspective view illustrating a configuration of a filter circuit according to a third embodiment.

### DESCRIPTION OF EMBODIMENTS

### First Embodiment

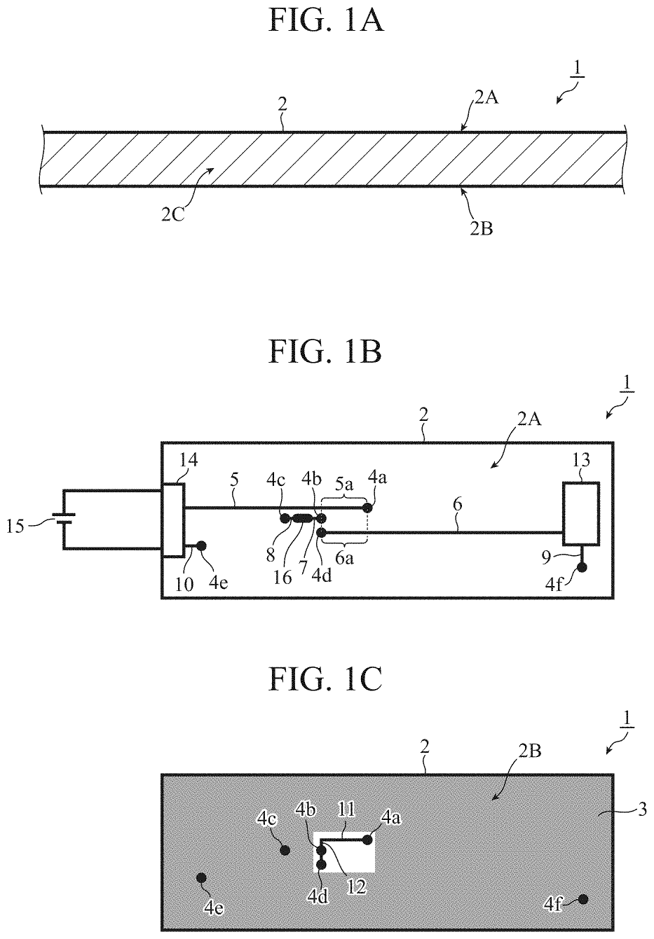

FIG. 1A is a cross-sectional view illustrating a printed circuit board 2 provided with a filter circuit 1 according to the first embodiment. FIG. 1B is a plan view illustrating the filter circuit 1 provided in an upper wiring layer 2A of the printed circuit board 2. FIG. 1C is a plan view illustrating the filter circuit 1 provided in a lower wiring layer 2B of the printed circuit board 2. The filter circuit 1 is, for example, a noise filter that removes electromagnetic noise in a high frequency band leaking from a circuit element 13, and is provided on the printed circuit board 2.

As illustrated in FIG. 1A, the printed circuit board 2 is a double-sided printed circuit board having a first surface and a second surface opposite to the first surface. The first surface is the upper wiring layer 2A, and the second surface is the lower wiring layer 2B. An insulating layer 2C is interposed between the upper wiring layer 2A and the lower wiring layer 2B. The printed circuit board 2 has a structure in which the upper wiring layer 2A, the insulating layer 2C, and the lower wiring layer 2B are laminated in the thickness direction. The insulating layer 2C is made of, for example, an electrically insulating material such as a non-conductive resin.

In FIG. 1C, a ground conductor surface 3 is provided in the lower wiring layer 2B of the printed circuit board 2. In addition, the printed circuit board 2 is provided with vias 4a, 4b, 4c, 4e, and 4f that penetrate the insulating layer 2C as illustrated in FIGS. 1B and 1C. The vias 4a, 4b, 4c, 4e, and 4f are holes penetrating the insulating layer 2C, and the holes are filled with, for example, a conductive paste. Further, the holes may have metal layers that are formed therein by electroless plating and that are made of copper or the like.

In FIGS. 1B and 1C, wiring patterns 5, 6, 7, 8, 9, and 10 are formed in the upper wiring layer 2A, and wiring patterns 11 and 12 are formed in the lower wiring layer 2B so as not to be electrically connected to the ground conductor surface 3. These wiring patterns are made of a conductor such as a copper foil.

The upper wiring layer 2A is provided with the circuit element 13, a connector circuit 14, an external power supply 15, and a bypass capacitor 16 for removing electromagnetic noise. The circuit element 13 is an electronic component such as an LSI or an IC. The external power supply 15 is, for example, a DC-DC converter or an in-vehicle battery. The connector circuit 14 is electrically connected to the external power supply 15.

The wiring pattern 5 is a first wire provided in the upper wiring layer 2A of the printed circuit board 2, and the first wire has one end electrically connected to a positive terminal of the external power supply 15 through the connector circuit 14. The wiring pattern 6 is a fourth wire provided so as to partially face the wiring pattern 5 in the upper wiring layer 2A which is on the same plane as the wiring pattern 5. As illustrated in FIG. 1B, a portion of the wiring pattern 5 facing the wiring pattern 6 is defined as a wiring portion 5a, and a portion of the wiring pattern 6 facing the wiring pattern 5 is defined as a wiring portion 6a. The wiring portion 5a and the wiring portion 6a are provided at positions facing each other and close to each other.

The wiring pattern 7 is a lead wire electrically connected to one of a pair of electrode terminals included in the bypass capacitor 16, and the wiring pattern 8 is a lead wire electrically connected to the other electrode terminal. The wiring pattern 9 is a ground wire electrically connected to a ground terminal of the circuit element 13. In addition, the wiring pattern 10 is a ground wire electrically connected to a ground terminal of the connector circuit 14.

The wiring pattern 11 is a second wire that is provided so as not to be electrically connected to the ground conductor surface 3 in the lower wiring layer 2B which is on a plane different from the wiring pattern 5, and provided at a position overlapping the wiring pattern 5 in planar view. The wiring pattern 12 is a third wire extending from one end of the wiring pattern 11. As illustrated in FIG. 1C, the wiring pattern 11 and the wiring pattern 12 each have a bent portion bent at a right angle. However, instead of the wiring pattern 11 and the wiring pattern 12, a linear wiring pattern may be used, or a circular or elliptical wiring pattern may be used.

One end of the wiring portion 5a of the wiring pattern 5 is electrically connected to an opposite end of the wiring pattern 11 from the wiring pattern 12 by the via 4a which is a first connection conductor. The wiring pattern 7 connected to one of the electrode terminals of the bypass capacitor 16 is electrically connected to the wiring pattern 12 by the via 4b which is a second connection conductor. The wiring pattern 8 connected to the other electrode terminal of the bypass capacitor 16 is electrically connected to the ground conductor surface 3 by the via 4c which is a third connection conductor.

One end of the wiring portion 6a of the wiring pattern 6 is electrically connected to the wiring pattern 12 by the via 4d which is a fourth connection conductor. In addition, the wiring pattern 9 connected to the ground terminal of the circuit element 13 is electrically connected to the ground conductor surface 3 by the via 4f The wiring pattern 10 connected to the ground terminal of the connector circuit 14 is electrically connected to the ground conductor surface 3 by the via 4e.

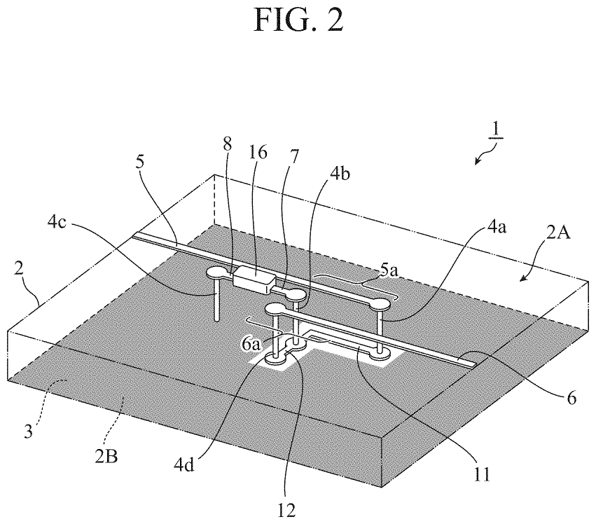

FIG. 2 is a transparent perspective view illustrating a configuration of the filter circuit 1. In FIG. 2, the end of the wiring portion 5a is electrically connected to the wiring pattern 11 by the via 4a, and the end of the wiring portion 6a is electrically connected to the wiring pattern 12 by the via 4d. Since the wiring pattern 5 and the wiring pattern 6 are provided in parallel, a first structure including the wiring portion 5a, the via 4a, and the wiring pattern 11 faces a second structure including the via 4d and the wiring portion 6a so as to be close to each other.

The wiring portion 5a and the wiring portion 6a are electrically connected through the via 4a, the wiring pattern 11, the wiring pattern 12, and the via 4d. That is, the wiring portion 5a and the wiring portion 6a are connected in series through the via 4a, the wiring pattern 11, the wiring pattern 12, and the via 4d. Since currents flow through the wiring portion 5a and the wiring portion 6a in the same direction, the direction of the current flowing through the first structure and the direction of the current flowing through the second structure are the same as each other. Furthermore, due to the parasitic inductance, the directions of magnetic fluxes generated between the first structure and the second structure are also substantially the same.

One of the electrode terminals of the bypass capacitor 16 is electrically connected to the wiring pattern 12 through the wiring pattern 7 and the via 4b, and the other electrode terminal is electrically connected to the ground conductor surface 3 through the wiring pattern 8 and the via 4d. An opposite end of the wiring pattern 5 from the wiring portion 5a is electrically connected to the external power supply 15 through the connector circuit 14, and an opposite end of the wiring pattern 6 from the wiring portion 6a is electrically connected to a power supply terminal of the circuit element 13.

The filter circuit 1 includes the first structure, the second structure, and the bypass capacitor 16. The first structure and the second structure have a pair of parasitic inductances that are magnetically coupled to each other to cause mutual induction.

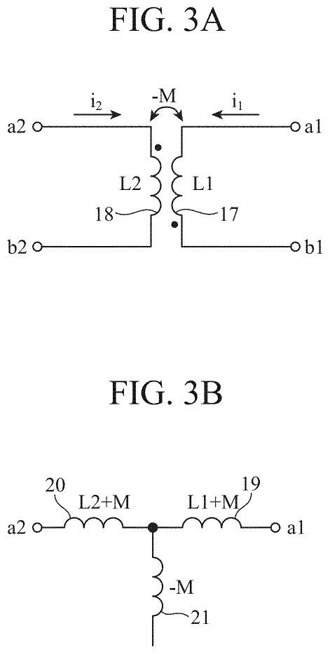

FIG. 3A is a circuit diagram schematically illustrating a mutual induction circuit including a parasitic inductor of the first structure including the wiring portion 5a which is the first wire, the via 4a which is the first connection conductor, and the wiring pattern 11 which is the second wire, and a parasitic inductor of the second structure including the via 4d which is the fourth connection conductor and the wiring portion 6a which is the fourth wire. FIG. 3B is a circuit diagram illustrating a T-type equivalent circuit of the mutual induction circuit illustrated in FIG. 3A.

In FIGS. 3A and 3B, when a current i₁ from a node a1 flows into a parasitic inductor 17 and a current i₂ from a node a2 flows into a parasitic inductor 18, a mutual inductance —M is formed between the parasitic inductor 17 and the parasitic inductor 18. In a case where nodes b1 and b2 are at a common potential, the mutual induction circuit can be considered as the equivalent circuit including three inductors 19, 20 and 21 respectively having three inductances L1+M, L2+M and −M illustrated in FIG. 3B. The equivalent circuit illustrated in FIG. 3B is referred to as a T-type equivalent circuit.

The magnitude M of the mutual inductance between the first structure including the wiring portion 5a, the via 4a, and the wiring pattern 11 and the second structure including the via 4d and the wiring portion 6a is given by Formula (1) below. In Formula (1) below, “k” is a coupling coefficient.

M=k×(L1×L2)^{1/2} (1)

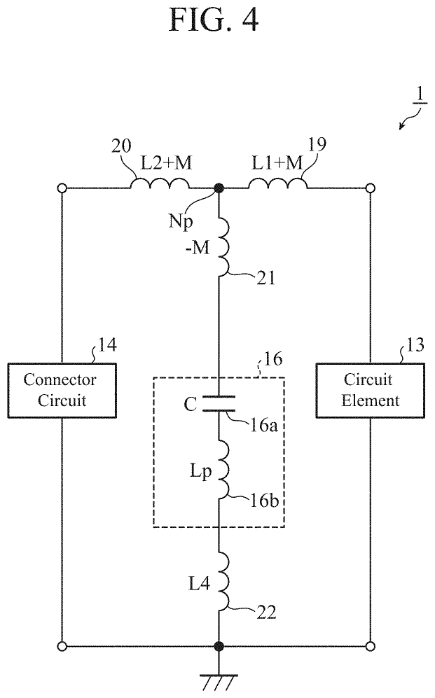

FIG. 4 is a circuit diagram schematically illustrating a main part of the equivalent circuit of the filter circuit 1. The equivalent circuit illustrated in FIG. 4 includes the circuit element 13, the T-type equivalent circuit illustrated in FIG. 3B, the bypass capacitor 16, the parasitic inductor 22 having a wiring inductance L4, and the connector circuit 14. The equivalent inductance of the inductor 19 is L1+M, and the equivalent inductance of the inductor 20 is L2+M.

The bypass capacitor 16 includes a capacitor component 16a of capacitance C and a parasitic inductor 16b having a residual inductance Lp that is an equivalent series inductance (ESL). The parasitic inductor 22 is formed by the vias 4b and 4c illustrated in FIG. 2. In FIG. 4, the other circuit elements included in the filter circuit 1 are not illustrated for convenience of description. The other circuit elements include, for example, a resistance component and a parasitic inductor component of the wiring pattern 7.

The filter circuit 1 has a bypass circuit including the via 4b, the wiring pattern 7, the bypass capacitor 16, the wiring pattern 8, and the via 4c. In this bypass circuit, the inductor 21 having the negative inductance −M equivalently appears as illustrated in FIG. 4 when the first structure including the wiring portion 5a, the via 4a, and the wiring pattern 11 and the second structure including the via 4d and the wiring portion 6a are magnetically coupled. That is, the inductor 21 is equivalently connected to a series connection point Np between the inductors 19 and 20. The inductor 21 having the negative inductance −M, the capacitor component 16a, and the parasitic inductor 16b are connected in series with the bypass circuit.

The wiring inductance L4 is approximately calculated based on the dimensions (for example, length and via diameter) of the via 4b and the via 4c. The residual inductance Lp can be calculated by measuring the characteristics of the bypass capacitor 16.

In the filter circuit 1, the negative inductance −M is designed in such a manner that the impedances are canceled out for the negative inductance −M, the via 4b, the wiring inductance L4, and the residual inductance Lp of the bypass capacitor 16. As a result, the impedance of the bypass circuit is equivalent to the impedance of only the capacitor component 16a, and the negative inductance −M can be designed to have an optimum value using Formula (1).

The bypass path in the bypass circuit does not substantially include an inductance component. Therefore, even if the frequency of the electromagnetic noise propagating through the wiring pattern 6 is high, deterioration in bypass performance can be prevented. Note that the negative inductance −M may be designed in consideration of parasitic inductances of the wiring patterns 7 and 8 that are lead wires of the bypass capacitor 16.

In order to cancel the parasitic inductance in the bypass circuit, it is generally conceivable to add an electronic component such as an inductor. However, the addition of a new electronic component causes an increase in manufacturing cost of the printed circuit board 2, and the new electronic component may electromagnetically act on the wiring or the electronic component in the printed circuit board 2 and have an adverse effect thereon. On the other hand, the filter circuit 1 can suppress the deterioration of the bypass performance without adding a new electronic component.

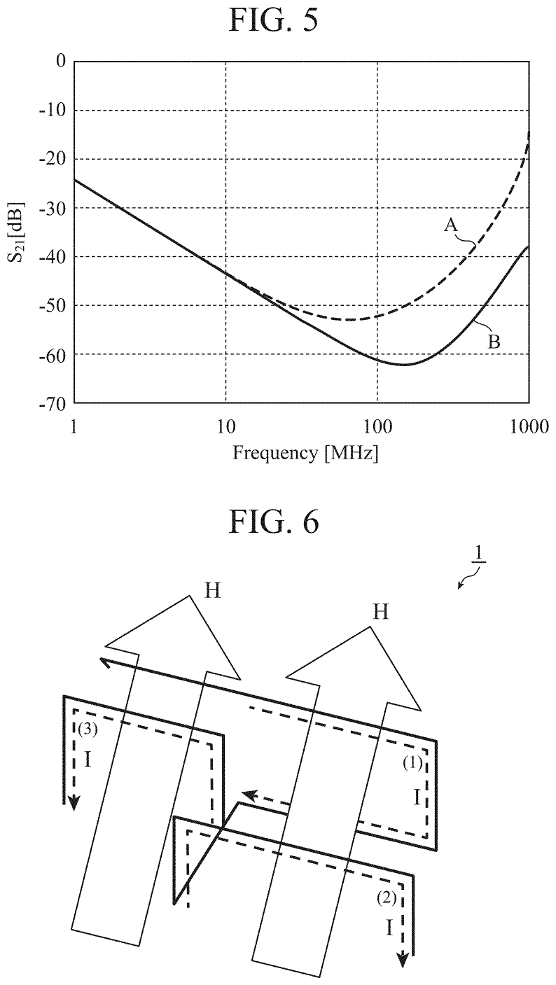

FIG. 5 is a graph illustrating an electromagnetic-field calculation result of an S parameter (S₂₁) representing the filter performance of a conventional filter circuit and the filter performance of the filter circuit 1 according to the first embodiment. The horizontal axis which is a logarithmic axis represents a frequency, and the vertical axis represents a pass characteristic of the S parameter (dB). In the electromagnetic-field calculation, a chip capacitor having a capacitance C of 0.1 (μF) is used as the bypass capacitor, and the termination impedance at an input/output terminal is 50 (Ω).

The broken line curve with a reference sign A indicates the electromagnetic-field calculation result of the filter circuit 1, and the solid line curve with a reference sign B indicates the electromagnetic-field calculation result of the conventional filter circuit. In FIG. 5, the conventional filter circuit is the filter circuit described in Patent Literature 1, and has the same configuration as that of the filter circuit 1 except that one of the electrode terminals of the bypass capacitor 16 is connected to the end of the wiring portion 6a and the other electrode terminal is connected to the ground conductor surface 3 by a via. The wiring portion 5a and the wiring portion 6a in the conventional filter circuit are about twice longer than the wiring portion 5a and the wiring portion 6a in the filter circuit 1. As described above, the filter circuit 1 has a smaller structure than the filter circuit described in Patent Literature 1.

As is clear from the electromagnetic-field calculation results A and B, in the filter circuit 1, deterioration of filter performance on a higher frequency side with respect to about 50 (MHz) which is a resonance frequency is improved as compared with the conventional filter circuit. In the filter circuit 1, the lengths of the wiring portion 5a and the wiring portion 6a can be decreased as compared with the conventional filter circuit. The filter circuit 1 can obtain a large mutual inductance, thereby being capable of sufficiently suppressing the deterioration in performance of the bypass circuit.

FIG. 6 is a diagram illustrating a wiring loop (1), a wiring loop (2), and a wiring loop (3) in the filter circuit 1. In FIG. 6, the solid line indicates a wiring pattern, the arrowed dotted line indicates a direction of a current I flowing through each of the wiring loop (1), the wiring loop (2), and the wiring loop (3) formed by the wiring pattern, and the open arrow indicates a direction of a magnetic field H.

The wiring loop (1) corresponds to the inductor 20 in the equivalent circuit illustrated in FIG. 4. For example, the wiring loop (1) is the first structure constituted by a wiring loop including the wiring portion 5a, the via 4a, and the wiring pattern 11 in the filter circuit 1 illustrated in FIG. 2.

The wiring loop (2) corresponds to the inductor 19 in the equivalent circuit illustrated in FIG. 4. For example, the wiring loop (2) is the second structure constituted by a wiring loop including the via 4d and the wiring portion 6a in the filter circuit 1 illustrated in FIG. 2.

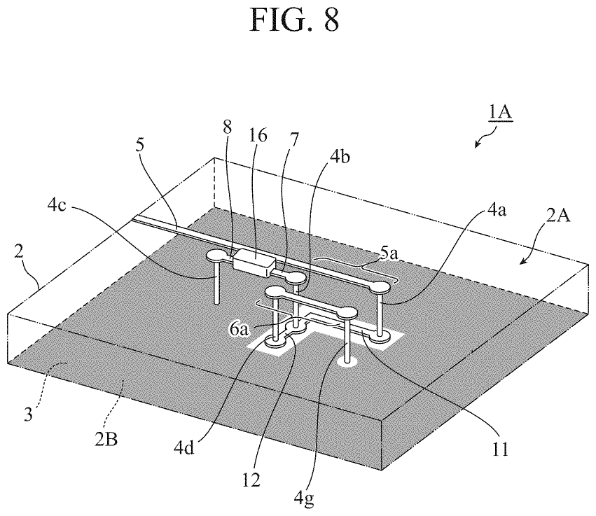

In addition, the wiring loop (2) is a second structure constituted by a wiring loop including a via 4d, a wiring portion 6a, and a via 4g in a filter circuit 1A illustrated in FIG. 8 to be described later.

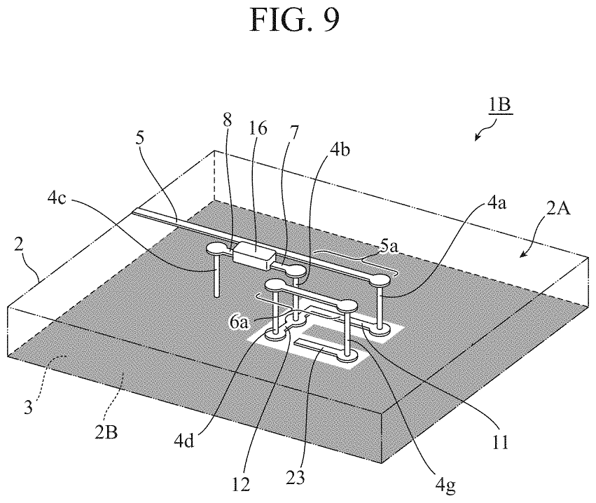

Furthermore, the wiring loop (2) is a second structure constituted by a wiring loop including a via 4d, a wiring portion 6a, a via 4g, and a wiring pattern 23 in a filter circuit 1B illustrated in FIG. 9 to be described later.

The wiring loop (3) corresponds to a path of the bypass capacitor 16 in the equivalent circuit illustrated in FIG. 4. For example, the wiring loop (3) is a third structure constituted by a wiring loop including the via 4b, the bypass capacitor 16, and the via 4c in any of the filter circuit 1 illustrated in FIG. 2, the filter circuit 1A illustrated in FIG. 8 to be described later, and the filter circuit 1B illustrated in FIG. 9 to be described later. Note that, in FIG. 2, the third structure is a wiring loop including the via 4b, the wiring pattern 7, the bypass capacitor 16, the wiring pattern 8, and the via 4c.

As illustrated in FIG. 2, the third structure constituted by the via 4b, the wiring pattern 7, the bypass capacitor 16, the wiring pattern 8, and the via 4c is provided at a position outside the space where the first structure constituted by the wiring portion 5a, the via 4a, and the wiring pattern 11 and the second structure constituted by the via 4d and the wiring portion 6a face each other.

That is, the wiring loop (3) is disposed at a position outside the space where the wiring loop (1) and the wiring loop (2) face each other. The third structure does not face the first structure and the second structure, and the wiring loop (3) does not face the wiring loop (1) and the wiring loop (2).

As illustrated in FIG. 6, the currents I flow in the same direction in the wiring loop (1) and the wiring loop (2), so that the magnetic field H directed from the wiring loop (2) to the wiring loop (1) is generated. The magnetic field H is also interlinked with the path of the wiring loop (3).

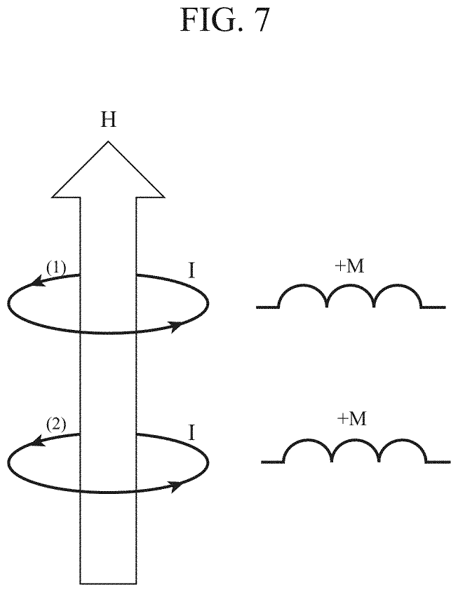

FIG. 7 is a diagram illustrating a relationship between both the wiring loop (1) and the wiring loop (2) facing each other and the magnetic field H generated in the wiring loop (1) and the wiring loop (2) in the filter circuit 1. As illustrated in FIG. 7, the currents I in the same direction flow through the wiring loop (1) and the wiring loop (2). Thus, the inductor 19 corresponding to the wiring loop (2) and the inductor 20 corresponding to the wiring loop (1) are magnetically coupled, and the inductors 19 and 20 each increase by an inductance+M.

As illustrated in FIG. 6, the direction of the current I flowing through the wiring loop (3) is opposite to the direction of the currents I flowing through the wiring loop (1) and the wiring loop (2). Therefore, when the magnetic field H generated by the currents I flowing through the wiring loop (1) and the wiring loop (2) interlinks with the path of the wiring loop (3), a negative inductance −M is generated in the wiring loop (3). Accordingly, in the filter circuit 1, decoupling performance of the bypass path of the capacitor is improved.

Note that the negative inductance −M generated in the wiring loop (3) is different from the inductance in the inductor 21 illustrated in FIG. 4.

As described above, the filter circuit 1 according to the first embodiment includes the wiring pattern 5 provided in the upper wiring layer 2A of the printed circuit board 2, the wiring pattern 11 provided in the lower wiring layer 2B of the printed circuit board 2, the wiring pattern 12 extending from the end of the wiring pattern 11, the wiring pattern 6 provided so as to partially face the wiring pattern 5 in the upper wiring layer 2A, the bypass capacitor 16 provided in the upper wiring layer 2A and connected to the wiring pattern 12 and the ground conductor surface 3, the via 4a connecting the end of the wiring pattern 5 and the wiring pattern 11, and the via 4d connecting the wiring pattern 12 and the wiring pattern 6. The first structure including the wiring pattern 5, the via 4a, and the wiring pattern 11 faces the second structure including the via 4d and the wiring pattern 6. Since the lengths of the wiring portion 5a and the wiring portion 6a can be decreased, the structure can be downsized. In addition, the first and second structures form a mutual inductance by magnetic coupling, and the parasitic inductance of the bypass circuit including the bypass capacitor 16 is canceled by the negative inductance −M equivalently appearing corresponding to the mutual inductance. Thus, the filter circuit 1 can be downsized in structure and can suppress the deterioration of bypass performance due to the parasitic inductance of the wiring used for mounting the bypass capacitor 16.

In the above description, the printed circuit board 2 is a double-sided printed circuit board having a two-layer structure, but it is not limited thereto. The filter circuit 1 according to the first embodiment can be provided on a multilayer printed circuit board having three or more wiring layers. In addition, the filter circuit 1 can be formed on an element other than the printed circuit board by configuring the wiring and the connection conductor as a bus bar.

In addition, the filter circuit 1 may be provided with a power supply element as an internal power supply in the printed circuit board 2 instead of the external power supply 15. The filter circuit 1 has the first structure and the second structure, thereby being capable of suppressing propagation of high-frequency electromagnetic noise to the power supply element.

In addition, in the filter circuit 1 according to the first embodiment, the third structure including the via 4b, the bypass capacitor 16, and the via 4c is provided at a position outside the space where the first structure including the wiring portion 5a, the via 4a, and the wiring pattern 11 and the second structure including the via 4d and the wiring portion 6a face each other. In the filter circuit 1, the direction of the current I flowing through the bypass path of the capacitor is opposite to the direction of the currents I flowing through the wiring loop (1) and the wiring loop (2). Therefore, when the magnetic field H generated by the currents I flowing through the wiring loop (1) and the wiring loop (2) interlinks with the bypass path of the capacitor, an inductance −M is generated in the wiring loop (3) in addition to the inductance −M in the inductor 21 illustrated in FIG. 4. As a result, in the filter circuit 1, decoupling performance of the bypass path of the capacitor can be improved.

### Second Embodiment

The first embodiment has described the wiring loop (2) in which a loop surface is defined by two sides which are defined by the via 4d and the wiring portion 6a, respectively. On the other hand, the second embodiment will describe a filter circuit having, as a second structure, a wiring loop (2) in which a loop surface is defined by three sides.

FIG. 8 is a transparent perspective view illustrating a configuration of the filter circuit 1A according to the second embodiment. In FIG. 8, the same components as those in FIG. 2 are identified by the same reference signs. One end of a wiring portion 5a in the filter circuit 1A is electrically connected to a wiring pattern 11 by a via 4a. One end of a wiring portion 6a is electrically connected to a wiring pattern 12 by a via 4d. A via 4g is a fifth connection conductor penetrating from an upper wiring layer 2A to a lower wiring layer 2B in a printed circuit board 2. A first structure of the filter circuit 1A is the wiring loop (1) illustrated in FIGS. 6 and 7, a second structure is the wiring loop (2) illustrated in FIGS. 6 and 7, and a third structure is the wiring loop (3) illustrated in FIGS. 6 and 7.

In addition, similar to the wiring pattern 11 and the wiring pattern 12, the conductor around the via 4g is removed so as not to be electrically connected to the ground conductor surface 3.

In the filter circuit 1A, the first structure includes the wiring portion 5a, the via 4a, and the wiring pattern 11, and the third structure includes the via 4b, a wiring pattern 7, a bypass capacitor 16, a wiring pattern 8, and a via 4c. In addition, the second structure is a loop structure in which a loop surface is defined by three sides which are defined by the via 4d, the wiring portion 6a, and the via 4g, respectively.

As illustrated in FIG. 8, since the wiring pattern 5 and the wiring portion 6a are provided in parallel, the first structure including the wiring portion 5a, the via 4a, and the wiring pattern 11 faces the second structure including the via 4d, the wiring portion 6a, and the via 4g so as to be close to each other. The wiring portion 5a and the wiring portion 6a are electrically connected through the via 4a, the wiring pattern 11, the wiring pattern 12, and the via 4d. That is, the wiring portion 5a and the wiring portion 6a are connected in series through the via 4a, the wiring pattern 11, the wiring pattern 12, and the via 4d.

Since currents flow through the wiring portion 5a and the wiring portion 6a in the same direction, the direction of the current flowing through the first structure and the direction of the current flowing through the second structure are the same as each other. Furthermore, due to the parasitic inductance, the directions of magnetic fluxes generated between the first structure and the second structure are also substantially the same. One of the electrode terminals of the bypass capacitor 16 is electrically connected to the wiring pattern 12 through the wiring pattern 7 and the via 4b, and the other electrode terminal of the bypass capacitor 16 is electrically connected to the ground conductor surface 3 through the wiring pattern 8 and the via 4c.

Similar to the filter circuit 1, the filter circuit 1A includes the first structure, the second structure, and the third structure including the bypass capacitor 16. In the filter circuit 1A, the first structure and the second structure have a pair of parasitic inductances that are magnetically coupled to each other to cause mutual induction. The magnetic field H generated from the wiring loop (2) illustrated in FIG. 6 is stronger when the wiring loop (2) has a loop surface defined by three sides, that is, as the wiring loop (2) has a shape closer to a closed loop.

The filter circuit 1A has the second structure in which the loop surface is defined by three sides that are defined by the via 4d, the wiring portion 6a, and the via 4g, respectively, and thus can increase the magnetic coupling between the first structure and the second structure as compared with the loop defined by two sides, that is, the second structure in which each of the via 4d and the wiring portion 6a is regarded as one side, in the filter circuit 1.

As described above, the filter circuit 1A according to the second embodiment includes the via 4g. The second structure of the filter circuit 1A includes the via 4g in addition to the wiring portion 6a and the via 4d. The first structure and the second structure form a mutual inductance by magnetic coupling, and the parasitic inductance of the bypass circuit including the bypass capacitor 16 is canceled by a negative inductance −M equivalently appearing corresponding to the mutual inductance. Since the second structure of the filter circuit 1A has a loop defined by three sides, a stronger magnetic coupling than the loop defined by two sides in the filter circuit 1 is formed. Thus, in the filter circuit 1A, the effect of canceling the parasitic inductance of the bypass circuit is greater than that in the filter circuit 1. The parasitic inductance of the bypass circuit is canceled, whereby the filter circuit 1A can suppress the deterioration of bypass performance due to the parasitic inductance of wiring used for mounting the bypass capacitor 16. Furthermore, in the filter circuit 1A, the wiring portion 5a and the wiring portion 6a can be decreased in length as compared with the conventional technique, whereby the structure can be downsized.

In the above description, the printed circuit board is a double-sided printed circuit board having a two-layer structure, but it is not limited thereto. The filter circuit 1A according to the second embodiment can be provided on a multilayer printed circuit board having three or more wiring layers. In addition, the filter circuit 1A can be formed on an element other than the printed circuit board by configuring the wiring and the connection conductor as a bus bar.

The filter circuit 1A has the first structure and the second structure, thereby being capable of suppressing propagation of high-frequency electromagnetic noise to a power supply element.

### Third Embodiment

The second embodiment has described the wiring loop (2) in which a loop surface is defined by three sides which are defined by the via 4d, the wiring portion 6a, and the via 4g, respectively. On the other hand, a third embodiment will describe a filter circuit having, as a second structure, a wiring loop (2) in which a loop surface is defined by four sides.

FIG. 9 is a transparent perspective view illustrating a configuration of the filter circuit 1B according to the third embodiment. In FIG. 9, the same components as those in FIGS. 2 and 8 are identified by the same reference signs. One end of a wiring portion 5a in the filter circuit 1B is electrically connected to a wiring pattern 11 by a via 4a. One end of a wiring portion 6a is electrically connected to a wiring pattern 12 by a via 4d. A via 4g is a fifth connection conductor penetrating from an upper wiring layer 2A to a lower wiring layer 2B in a printed circuit board 2, and electrically connects the other end of the wiring portion 6a and a wiring pattern 23. A first structure of the filter circuit 1B is the wiring loop (1) illustrated in FIGS. 6 and 7, a second structure is the wiring loop (2) illustrated in FIGS. 6 and 7, and a third structure is the wiring loop (3) illustrated in FIGS. 6 and 7.

The wiring pattern 11 is a second wire that is provided so that the second wire is not electrically connected to a ground conductor surface 3 in the lower wiring layer 2B which is on a plane different from the wiring pattern 5, and that is provided at a position overlapping a wiring pattern 5 in planar view. The wiring pattern 12 is a third wire extending from one end of the wiring pattern 11. The wiring pattern 11 and the wiring pattern 12 each have a bent portion bent at a right angle. The filter circuit 1B further includes the wiring pattern 23.

The wiring pattern 23 is a fifth wire that is provided at a position overlapping the wiring portion 6a in planar view in the lower wiring layer 2B which is on a plane different from the wiring portion 6a.

In addition, similar to the wiring pattern 11 and the wiring pattern 12, the conductor around the wiring pattern 23 is removed so as not to be electrically connected to the ground conductor surface 3.

In the filter circuit 1B, the first structure includes the wiring portion 5a, the via 4a, and the wiring pattern 11, and the third structure includes a via 4b, a wiring pattern 7, a bypass capacitor 16, a wiring pattern 8, and a via 4c. In addition, the second structure is a loop structure in which a loop surface is defined by four sides which are defined by the via 4d, the wiring portion 6a, the via 4g, and the wiring pattern 23, respectively.

As illustrated in FIG. 9, since the wiring pattern 5 and the wiring portion 6a are provided in parallel, the first structure including the wiring portion 5a, the via 4a, and the wiring pattern 11 faces the second structure including the via 4d, the wiring portion 6a, the via 4g, and the wiring pattern 23 so as to be close to each other. The wiring portion 5a and the wiring portion 6a are electrically connected through the via 4a, the wiring pattern 11, the wiring pattern 12, and the via 4d. That is, the wiring portion 5a and the wiring portion 6a are connected in series through the via 4a, the wiring pattern 11, the wiring pattern 12, and the via 4d.

Since currents flow through the wiring portion 5a and the wiring portion 6a in the same direction, the direction of the current flowing through the first structure and the direction of the current flowing through the second structure are the same as each other. Furthermore, due to the parasitic inductance, the directions of magnetic fluxes generated between the first structure and the second structure are also substantially the same. One of the electrode terminals of the bypass capacitor 16 is electrically connected to the wiring pattern 12 through the wiring pattern 7 and the via 4b, and the other electrode terminal of the bypass capacitor 16 is electrically connected to the ground conductor surface 3 through the wiring pattern 8 and the via 4c.

Similar to the filter circuit 1, the filter circuit 1B includes the first structure, the second structure, and the third structure including the bypass capacitor 16. In the filter circuit 1B, the first structure and the second structure have a pair of parasitic inductances that are magnetically coupled to each other to cause mutual induction. The magnetic field H generated from the wiring loop (2) illustrated in FIG. 6 is stronger when the wiring loop (2) has a loop surface defined by four sides, that is, as the wiring loop (2) has a shape closer to a closed loop.

The filter circuit 1B has the second structure in which the loop surface is defined by four sides which are defined by the via 4d, the wiring portion 6a, the via 4g, and the wiring pattern 23, respectively. Therefore, the filter circuit 1B can increase the magnetic coupling between the first structure and the second structure as compared with the second structure including the loop defined by two sides in the filter circuit 1 or the second structure including the loop defined by three sides in the filter circuit 1A.

As described above, the filter circuit 1B according to the third embodiment includes the wiring pattern 23 provided on a plane different from the wiring portion 6a and placed at a position overlapping the wiring portion 6a in planar view. The second structure includes the wiring pattern 23 in addition to the via 4d, the wiring portion 6a, and the via 4g. The first structure and the second structure form a mutual inductance by magnetic coupling, and the parasitic inductance of the bypass circuit including the bypass capacitor 16 is canceled by a negative inductance −M equivalently appearing corresponding to the mutual inductance. Since the second structure of the filter circuit 1B has a loop defined by four sides, a stronger magnetic coupling than the loop defined by two sides in the filter circuit 1 or the loop defined by three sides in the filter circuit 1A is formed. Thus, in the filter circuit 1B, the effect of canceling the parasitic inductance of the bypass circuit is greater than that in the filter circuit 1 or the filter circuit 1A. The parasitic inductance of the bypass circuit is canceled, whereby the filter circuit 1B can suppress the deterioration of bypass performance due to the parasitic inductance of wiring used for mounting the bypass capacitor 16. Furthermore, in the filter circuit 1B, the wiring portion 5a and the wiring portion 6a can be decreased in length as compared with the conventional technique, whereby the structure can be downsized.

In the above description, the printed circuit board is a double-sided printed circuit board having a two-layer structure, but it is not limited thereto. The filter circuit 1B according to the third embodiment can be provided on a multilayer printed circuit board having three or more wiring layers. In addition, the filter circuit 1B can be formed on an element other than the printed circuit board by configuring the wiring and the connection conductor as a bus bar.

The filter circuit 1B has the first structure and the second structure, thereby being capable of suppressing propagation of high-frequency electromagnetic noise to a power supply element.

It is to be noted that two or more of the above embodiments can be freely combined, or any component in the embodiments can be modified or omitted.

### INDUSTRIAL APPLICABILITY

The filter circuit according to the present disclosure can be used for, for example, a noise filter that removes electromagnetic noise in a high frequency band.

### REFERENCE SIGNS LIST

1: Filter circuit, 2: Printed circuit board, 2A: Upper wiring layer, 2B: Lower wiring layer, 2C: Insulating layer, 3: Ground conductor surface, 4a to 4f: Via, 5 to 12, 23: Wiring pattern, 5a and 6a: Wiring portion, 13: Circuit element, 14: Connector circuit, 15: External power supply, 16: Bypass capacitor, 16a: Capacitor component, 16b, 17, 18, and 22: Parasitic inductor, 19 to 21: Inductor

1. A filter circuit comprising:
a first wire;
a bypass capacitor;
a second wire provided on a plane different from the first wire and placed at a position overlapping the first wire in planar view;
a third wire extending from one end of the second wire;
a fourth wire provided on a same plane as the first wire and partially facing the first wire;
a first connection conductor that electrically connects one end of the first wire and an opposite end of the second wire from the third wire;
a second connection conductor that electrically connects a first electrode terminal of the bypass capacitor to the third wire;
a third connection conductor that connects a second electrode terminal of the bypass capacitor to a ground conductor surface; and
a fourth connection conductor that electrically connects the third wire and the fourth wire, wherein
a first structure including the first wire, the first connection conductor, and the second wire faces a second structure including the fourth wire and the fourth connection conductor.

2. The filter circuit according to claim 1, further comprising:
a power supply connected to an opposite end of the first wire from the end connected to the first connection conductor; and
a circuit element connected to an opposite end of the fourth wire from the end connected to the fourth connection conductor.

3. The filter circuit according to claim 1, wherein
a third structure including the second connection conductor, the bypass capacitor, and the third connection conductor is provided at a position outside a space where the first structure and the second structure face each other.

4. The filter circuit according to claim 2, wherein
a third structure including the second connection conductor, the bypass capacitor, and the third connection conductor is provided at a position outside a space where the first structure and the second structure face each other.

5. The filter circuit according to claim 3, further comprising
a fifth connection conductor connected to the fourth wire, wherein
the second structure includes the fifth connection conductor in addition to the fourth wire and the fourth connection conductor.

6. The filter circuit according to claim 4, further comprising
a fifth connection conductor connected to the fourth wire, wherein
the second structure includes the fifth connection conductor in addition to the fourth wire and the fourth connection conductor.

7. The filter circuit according to claim 5, further comprising
a fifth wire provided on the plane different from the fourth wire and placed at a position overlapping the fourth wire in planar view, wherein
the second structure includes the fifth wire in addition to the fourth wire, the fourth connection conductor, and the fifth connection conductor.

8. The filter circuit according to claim 6, further comprising
a fifth wire provided on the plane different from the fourth wire and placed at a position overlapping the fourth wire in planar view, wherein
the second structure includes the fifth wire in addition to the fourth wire, the fourth connection conductor, and the fifth connection conductor.
